(19) United States
(12) Patent Application Publication
(10) Pub. No.: US 2009/0108266 A1
(43) Pub. Date: Apr. 30, 2009

(54) Friction Control in Apparatus Having Wide Bandgap Semiconductors

(76) Inventors: Jonathan Hird, Cambridge (GB); Avik Chakravarty, Essex (GB); Satyendra Chakravarty, (US); Chhaya Chakravarty, (US)

Correspondence Address: TAROLLI, SUNDHEIM, COVELL & TUMMINO L.L.P., 1300 EAST NINTH STREET, SUITE 1700, CLEVEVLAND, OH, 44114, US

(21) Appl. No.: 12/200,360

(22) Filed: Aug. 28, 2008

(30) Foreign Application Priority Data
Oct. 31, 2007 (GB) 0721304.4

(51) Int. Cl. H01L 29/15; B24B 7/00; B24B 49/00

(52) U.S. Cl. 257/77; 451/64; 451/1; 257/E29.072

(57) ABSTRACT

Apparatus comprising, in use, a wide bandgap semiconductor, a conductor which is moveable relative to the semiconductor and means for applying a potential across the junction between a conductor and semiconductor to control the friction generated by the relative movement between the semiconductor and the conductor. A method of controlling friction between a wide bandgap semiconductor and conductor which are moveable relative to each other comprising applying a potential across the junction between the semiconductor and the conductor.

### RELATED APPLICATIONS

The present invention claims priority from British Patent Application No. GB0721304.4, filed 31 Oct. 2007.

### FIELD OF THE INVENTION

The invention relates to friction control in any tribological applications having wide bandgap semiconductors in sliding contact with conductors, for example tool machining apparatus.

### BACKGROUND TO THE INVENTION

Aside from its role as the world's most sought after gemstone, diamond remains one of the most prominently used abrasives and tool materials. Indeed, the market size of the diamond tool and abrasives market dwarves that of its gemstone counterpart. Emerging technologies utilising some of the more extreme properties of diamond such as its thermal conductivity, very low friction coefficient when sliding against itself, hardness and semiconducting properties are set to widen this gap further as markets open and are developed further.

The Achilles heel of diamond, however, is a thermo-chemical reaction that occurs (to varying degrees) when diamond is placed in contact with hot titanium (Ti), iron (Fe), molybdenum (Mo), nickel (Ni) and other reactive transition metals. Carbon atoms from the diamond diffuse through to the hot metal causing wear of the diamond. If the two counter bodies are sliding, heating due to friction will occur causing diffusion and/or graphitisation of the diamond. This will lead to very high friction coefficient causing breakage and wear of tool tips. Lubrication does not work as the reactions occur at “hot-spots”, i.e. localised microscopic areas of contact which develop high temperatures.

Effectively, this rules out the use of diamond in many types of machine tool and wear part applications and consequentially from a larger share of the machine tool sales market. Examples of other materials other than diamond more usually used as machine tools are silicon carbide (SiC), tungsten carbide (WC) and cubic-boron nitride (cBN). Similar reactions also occur with these materials and this also causes wear to the tool, poor surface finish to a work piece and in consequence, down-time which is detrimental to energy efficiency and employment costs.

The fundamental processes giving rise to friction between sliding bodies in close proximity is a key area of tribological research. Tribology is the science and technology of interacting surfaces in relative motion. In a fundamental paper entitled “A Physical Phenomenon and its applications to telegraphy, telephony, etc.” published on 26 May 1921, Johnsen and Rahbek investigated the effect of the application of an electric potential across a metal-semiconductor system comprising a metal plate laid on a block of semiconducting material. They found that the force required to separate the metal plate from the semiconducting block is increased by an amount dependent on the materials of the system and the magnitude of the electric potential across the system. The phenomenon is known as the Johnsen-Rahbeck effect and is discussed from a theoretical viewpoint in two later papers entitled “A simple theory of the Johnsen-Rahbeck effect” by R Atkinson (Brit J. Appl. Phys. 2 1969) and by C Balakrishnan: “Johnsen-Rahbeck effect with an electronic semiconductor” (Brit J. Appl. Phys. 1 1950). One may think of the Johnsen-Rahbek effect as the electrostatic attraction between a semiconductor and a metal plate. There is, however, no repulsive force.

Applications of the Johnsen-Rahbeck effect are described in GB 144,761. In one embodiment a layer of tin foil is glued to a face of slate tablet and a metal disc is placed on the opposed face. When a potential of 220V is applied to the system, the disc is firmly held to the slate table and if an attempt is made to slide the disc across the surface of the tablet, considerable frictional resistance is found. The attraction disappears when the potential is turned off. A similar result is found in a second embodiment of GB 144,761 where a band of semiconducting material having its top surface covered with tin foil is placed around a rotating metal cylinder. As long as a certain voltage is applied, there will be a large attraction between the band and metal cylinder. A variation of this second embodiment is described in a later application GB 146,757. Such applications may be termed semiconductor clamping devices or electrostatic chucks. The effect is widely used in the semiconductor industry for clamping and manipulating semiconductor wafers. A more recent paper “Generation mechanism of residual clamping force in a bipolar electrostatic clutch” by Kanno and Usui (J. Vac. Sci. Technol. B 21(6) 2003) revisits the mechanism.

The original paper by Johnsen-Rahbeck also discusses the effect of the application of a potential to a system comprising a semiconductor containing a considerable amount of moisture or impregnated by with an electrolytic salt solution. In such cases, the polarity of the semiconductor is critical. If the semiconductor is made positive relative to the contacting conductor, the attraction will decrease with application of a potential. If the potential is reversed, the large attraction reappears after a short period of time. This system may be termed an electrostatic clutch and is also described in UK patent application GB 194,747. The history of the electrostatic clutch is discussed in a paper entitled “Development of the electrostatic clutch” by C J Fitch published in the IBM Journal, January 1957.

A recent brief paper entitled “Electronic control of friction in silicon pn junctions” by Park et al. (Science 313 14 Jul. 2006) suggested that it may be possible to modulate friction in microelectromechanical systems (MEMS) and in the motion of nano-objects in patterned semiconductors by control of doping levels and electric fields. It was found that significant increases in friction may be achieved in the p-region compared to the n-region with a positive voltage applied to the semiconductor. No decreases in friction were observed thus the effect appears to be similar to that first reported by Johnsen and Rahbek.

### SUMMARY OF THE INVENTION

According to one aspect of the invention, there is provided apparatus comprising a wide bandgap semiconductor and a conductor having an interface with the semiconductor wherein a potential is applied across the interface between the semiconductor and conductor to control the friction generated between the semiconductor and the conductor.

According to a second aspect of the invention, there is provided a method of controlling friction between a wide bandgap semiconductor and conductor which have an interface between each other by applying a potential across the semiconductor and the conductor.

The wide bandgap semiconductor and conductor may be moveable relative to each other and the friction may be generated by this relative movement while the semiconductor and conductor are in contact. Alternatively, the friction may be generated without relative movement of the semiconductor and conductor, e.g. by static friction as motion is about to begin. Friction may thus be generated while the parts are stationary, e.g. in nano-machines such as semi-conductor gyros and accelerometers.

A wide bandgap semiconductor is one with electronic bandgaps larger than one electronvolt (eV). The gaps may be larger than two electronvolts for some applications. Such semiconductors may not easily form ohmic contacts and do not appear to have been considered in any of the prior art documents. The wide bandgap semiconductor may be a p-type or n-type semiconductor. For n-type semiconductors, the polarity of the current across the semiconductor/conductor junction is reversed compared to the polarity used for a p-type semiconductor.

The wide bandgap semiconductor may be formed from diamond. In view of the expense of diamond, the semiconductor may comprise a coating of a diamond material, e.g. diamond-like-carbon (DLC) (such coatings are relatively cheap and readily available and are used, for example, in some commercially available razor blades). Alternatively, the semiconductor may be formed from semiconducting carbide and nitride materials, e.g. silicon carbide (SiC), tungsten carbide (WC), boron nitride (BN), gallium nitride (GaN), or aluminium nitride (AlN). These materials may have been rendered semiconducting by application of an appropriate dopant during growth, or via ion implantation. The semiconductor may also be formed from a semiconducting polymer.

The conductor may be metallic, e.g. containing or comprising Fe, Ni, Mo, Al, Cu, Ag, Au, Sn, Mg, Vn, Mn, Cr, W and alloys e.g. stainless steel, carbon steels brass, bronze etc. which are amongst the most commonly utilised materials. Alternatively, the conductor may be non-metallic, e.g. formed from graphite. Alternatively, the conductor may be a standard semiconductor, e.g. silicon (Si) or germanium (Ge).

The potential applied should be such that a current is allowed to flow through the semiconductor-conductor junction. The potential applied may be very high, perhaps in the range 1 to 5 kV. Applying a high potential is likely to induce a high current which leads to Joule heating. Accordingly, the current may be limited (i.e. by using a load resistor) to a small current e.g. 0.1-10 μA (dependent on the height of the workfunction of the junction) to avoid Joule heating. Alternatively, in some applications, e.g. testing/de-icing, the current may not be limited whereby Joule heating is induced.

The potential may be applied to reduce or increase the friction for any tribological interaction involving a situation whereby any wide bandgap semiconductor and conductor slide against one another. The apparatus may be in the form of conventional-style bearings comprising a semiconductor made of semiconducting material and a conductor in the form of metal pairs with a potential being applied to reduce friction. Alternatively, the apparatus may be in the form of low-friction bearings with an integral braking mechanism activated by applying a potential difference between the semiconductor and metal to increase friction.

One important application is machining apparatus. The machining apparatus may comprise, in use, a semiconductor in the form of an item to be machined and a conductor in the form of a tool, e.g. drill, for machining the item. Alternatively, the item to be machined may be a conductor and the tool may be a semiconductor, i.e. diamond-tipped drill or cutting device. The machining of the item may be polishing the item. The potential may be applied to reduce friction whilst the tool is in contact with the item thereby reducing wear of the tool lending itself to a new generation of ‘smart tools’.

Simultaneously, it may be possible to further reduce friction by using knowledge of the temperatures generated at the tool tip using the thermoelectric effect as first described by E G Herbert (Inst. Mech. Eng. February 1926 p. 289). Accordingly, the apparatus may incorporate sensors with a signal processing circuit for sensing the temperature generated at a point of contact between the semiconductor and the conductor by the thermoelectric effect and control means for controlling friction using the sensed thermoelectric effect. Such thermoelectric emfs are measured in mV/Kelvin, thus it may be difficult to detect variation in the thermoelectric emf while an external potential is being applied. Temporarily switching off the applied potential may enable investigation of the heat generation using the thermoelectric effect. Using such data, it may be possible to modulate or alternate the friction by the applied potential. Stresses in the tool may also be measured and feedback loops incorporated to monitor and optimise the machining performance.

Other applications are in microelectricalmechanical systems (MEMS) and in devices for nanotechnology. The controllable friction could be utilised in novel clutch-type devices. Friction reduction will become increasingly more important in power generation with the advent of less efficient renewable sources such as in wind turbines. Most importantly, the technology is simple and existing machinery could be easily adapted to use it.

Friction control according to the invention is particularly useful in environments where lubrication is complicated, detrimental or impossible, e.g. in space or vacuum applications, or situations when a lubricant might contaminate the material being machined or the environment.

### BRIEF DESCRIPTION OF THE DRAWINGS

FIG. 1 is a simplified schematic of apparatus incorporating one aspect of the present invention;

FIG. 2 is a typical output trace from the strain gauges of the apparatus of FIG. 1 during a complete cycle of the stylus on the sample (left-right-left);

FIG. 3 is a graph of friction coefficient against position showing the friction reduction effect of the apparatus of FIG. 1 when a positive bias of 30 V was applied;

FIG. 4 is a graph of friction coefficient against position showing the friction memory effect of the apparatus of FIG. 1;

FIG. 5 is a graph of intensity against wavelength showing the typical spectrum observed from the interface of the apparatus of FIG. 1 when a positive bias is applied;

FIG. 6 is a schematic drawing of a tribological application having a wide bandgap semiconductor in sliding contact with a conductor;

FIG. 7 is a schematic drawing of apparatus for machining metal using a wide bandgap semiconducting tool;

FIG. 8 is a schematic drawing of journal bearings having bearings from a semiconducting material mounted on a metal journal, and

FIG. 9 is a schematic drawing of gear having a conducting gear and a semiconducting gear on a metal axle.

### DETAILED DESCRIPTION OF EMBODIMENTS

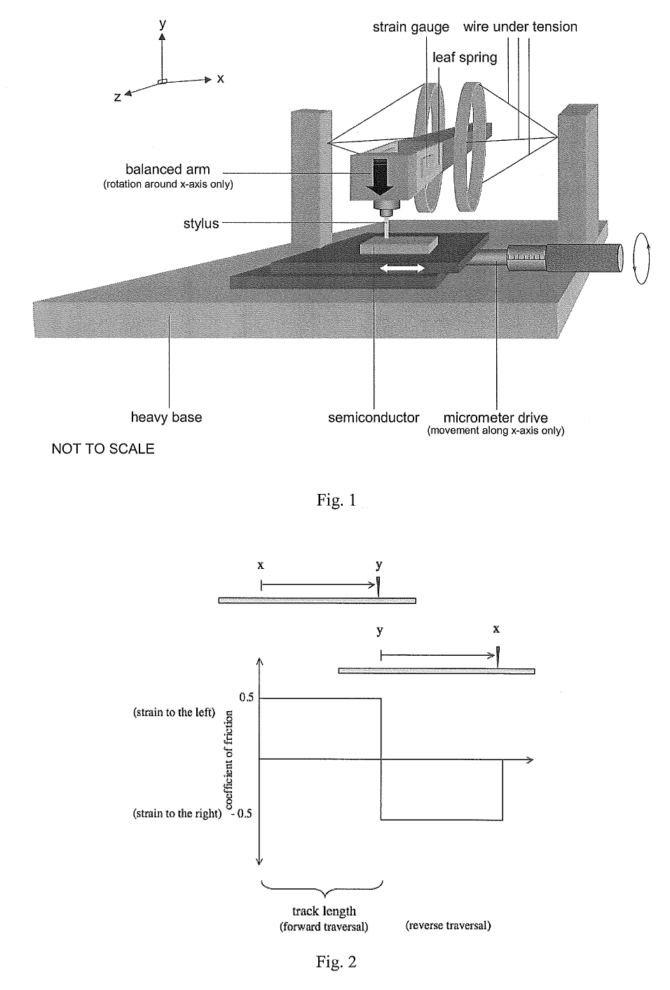

FIG. 1 is a schematic of apparatus demonstrating the principles of the invention. The apparatus is similar in operation to that described by I. P Hayward & J. E. Field ‘A computer-controlled friction measuring apparatus’ (J. Phys E: Sci. Instrum. 21 1988 p. 753-756). A semiconducting sample, e.g. p-type semiconducting diamond (bandgap≈3.6 eV), is mounted on an insulating block. The block is mounted on a motor-driven micrometer stage which is drive back and forth under a stylus. The stylus is a conductor and may be metallic, e.g. steel, aluminium (Al), copper (Cu), iron (Fe), nickel (Ni), molybdenum (Mo), platinum (Pt) or tungsten (W) or a non-metallic conductor, e.g. graphite from a pencil or it may be a standard semiconductor, e.g. silicon (Si) or germanium (Ge). The stylus is mounted by means of two leaf springs to an arm which is held rigid save for being allowed to rotate around the x-axis. Two strain gauges are attached to either side of each leaf spring. These are wired in a Wheatstone bridge arrangement, so that when the leaf springs are displaced (due to the frictional force between the sliding semiconducting sample against the stylus), the resultant strain to the left or right registers as an increase or decrease in resistance across the bridge. This resistance change is amplified by a strain gauge amplifier and is outputted as a positive or negative voltage and recorded by a computer. This voltage is directly proportional to the frictional force and further calibration yields the friction coefficient.

A semiconductor in contact with a metal forms the basis of a Schottky diode if a bias is applied across the junction. In the configuration of FIG. 1, the metal has only point contact with the semiconductor and is known as a cat's whisker diode. Electrical contact is made to the semiconductor via an ohmic contact. This ohmic contact is fabricated by depositing two or more metallic layers by magnetron sputtering. Electrical contact to the stylus may be applied directly by attaching a wire to the stylus, or through the metallic frame of the balanced arm (taking adequate precaution that false reading are not acquired by the strain gauges being mechanically influenced by the wires). In this manner, a positive or negative bias can be applied to the wide bandgap semiconductor. In the case where the semiconductor is positive, the current flow is easy and vice versa. It is found that when a potential is applied so that the current flow is easy (semiconductor positive with respect to the stylus), the sliding friction between the semiconductor pair is reduced dramatically.

FIG. 2 shows a typical output trace from the strain gauges recording one traversal to the left and back again, i.e. a complete cycle, of the stylus on the sample (left-right-left). The voltage is read at points along the track length (up to around 1.2 kHz). Calibration allows the friction coefficient at each point to be calculated and these values are stored on a computer. During the reverse traversal, the strain in the gauges is reversed and the voltage output is negative. The polarity of the coefficient of friction shown here is merely to indicate direction.

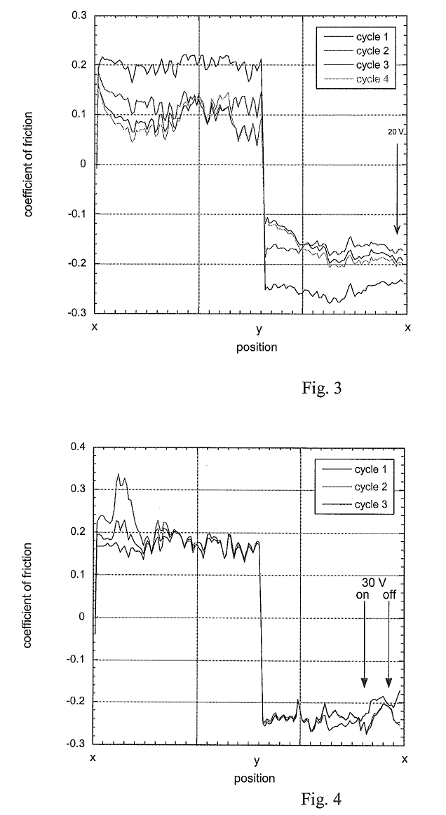

FIG. 3 shows the friction reduction effect of using a semiconductor (e.g. p-type semiconducting diamond) which is positively biased with respect to the metal stylus (in this case a gramophone needle) at the end of the first cycle (left-right-left). As shown, the friction coefficient decreased by approximately 50% rapidly and remained reduced until the bias was removed. The traversal speed was 0.2 mm s⁻¹ and the applied load was 14.2 g.

While the results are not as dramatic, if the semiconductor is given a negative bias, the friction can be made to increase.

FIG. 4 shows the ‘friction memory effect. Near the end of the first cycle (on the reverse traversal), 30 V was pulsed on and off rapidly. The friction coefficient momentarily decreases when the power is pulsed on and increases when the power is turned off. During cycle two, the friction coefficient is seen to increase significantly when the stylus traverses over the area where the potential was applied. The difference in friction is seen for a number of traversals after the initial pulse but it decreases with each traversal. The traversal speed was 0.2 mm s⁻¹ and the applied load was 0.14 N (14.2 g). It is thought that this occurs via the population of electron traps at defects produced during the frictional sliding.

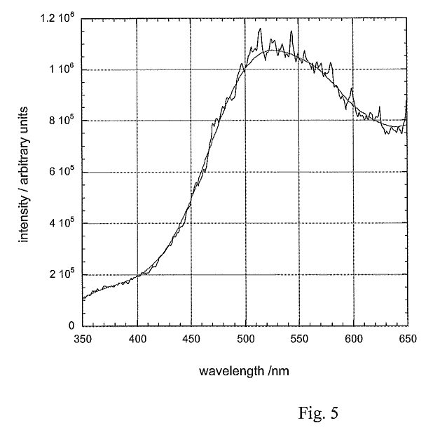

A luminescence is also associated with the invention. As shown in FIG. 5, the energy dispersion of the light emission occurring when the junction was positively biased, is indicative of electroluminescence of diamond similar to that obtained from diamond LEDS. The spectrum is little changed with a different metal as stylus which seemingly indicates that this effect is not a surface phenomenon. The light emission occurred when there was relative motion at the interface.

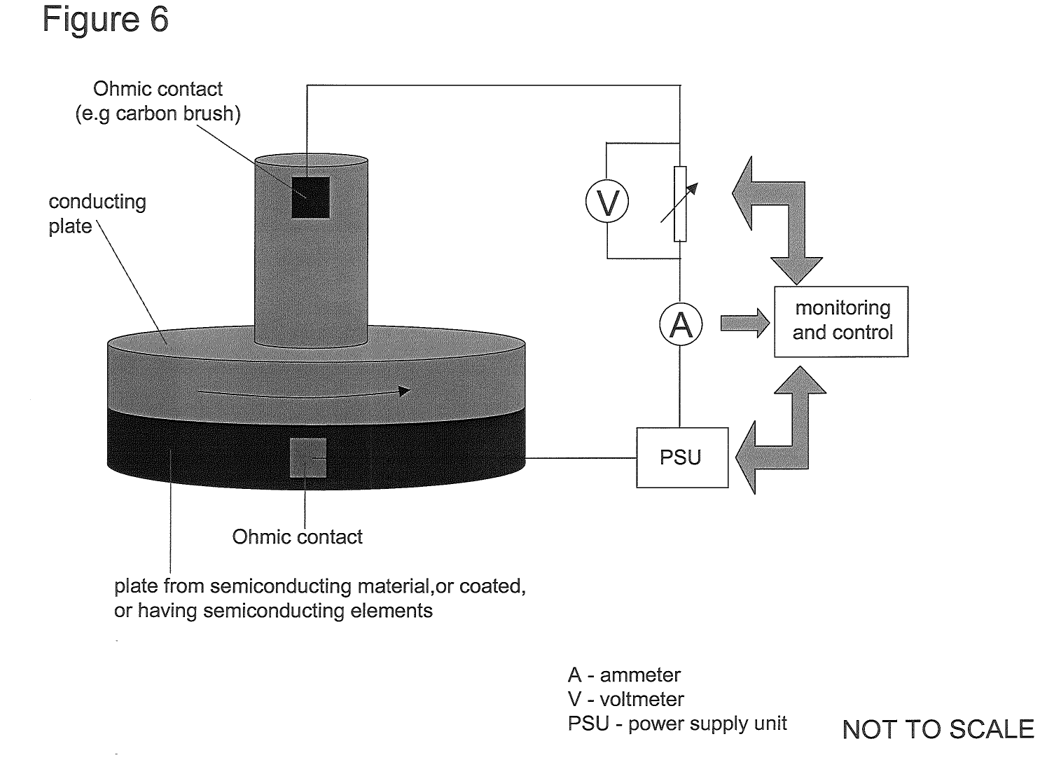

FIG. 6 is a schematic drawing of a tribological application having a lower plate comprising a wide bandgap semiconducting material in sliding or rotating contact with an upper plate made from a conducting material. The lower plate may comprise a coating of a semiconducting material. Ohmic contacts are formed on the upper and lower plates, e.g. a carbon brush for the conducting plate. A potential is applied across the semiconducting and conducting plates by the power supply unit (PSU) to induce a current across the junction between the plates. A load resistor is used to reduce the current. The potential and current are monitored and controlled to achieve the desired friction control. Although the conducting plate is shown as the upper plate, the relative positions of the two plates may be reversed. Similarly, although the conducting plate is shown as rotating and the semiconducting plate as stationary, this may also be reversed.

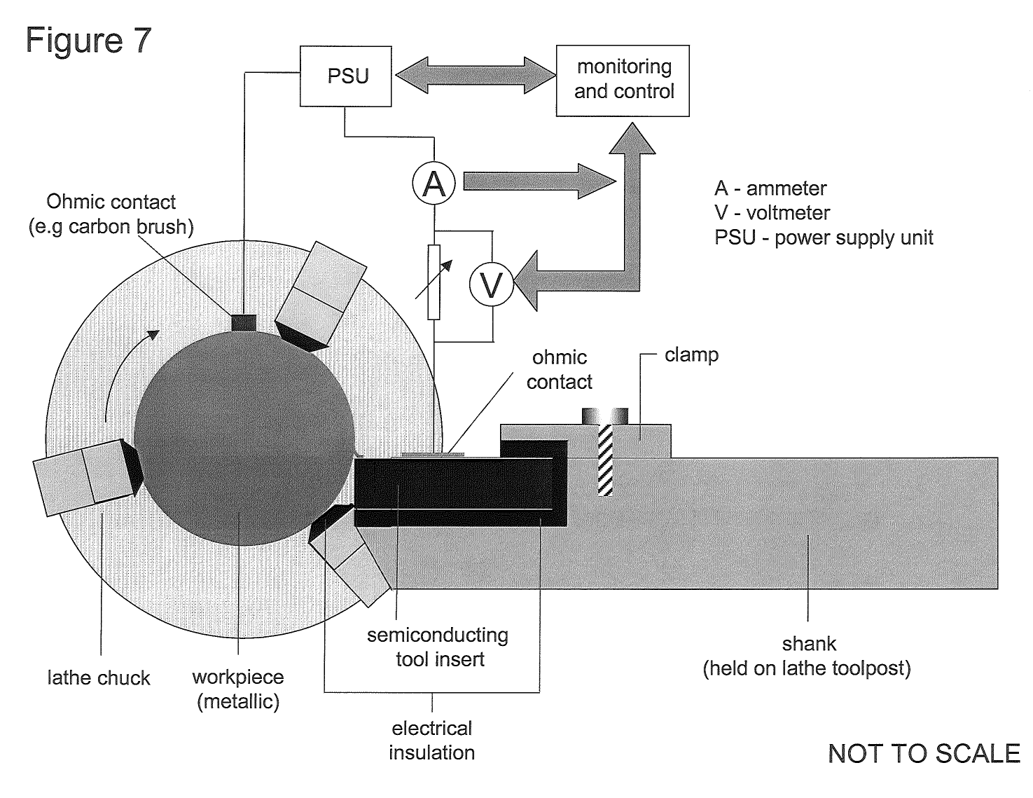

FIG. 7 is a schematic drawing of apparatus for machining a cylindrical metal workpiece using a wide bandgap semiconducting tool. The lathe jaws are fastened around the periphery of the workpiece and each is electrically insulated from the workpiece. A semiconducting tool insert is clamped in a shank mounted on the lathe toolpost (not shown) so that the tip of the tool is in contact with, and cuts, the work piece as the workpiece rotates. The tool bit is electrically insulated from the shank. Ohmic contacts are formed with the workpiece and tool, e.g. a carbon brush for the workpiece. A potential is applied across the semiconducting tool and workpiece to induce a current across the junction between the tool and workpiece. The potential and current are monitored and controlled to achieve the desired friction control.

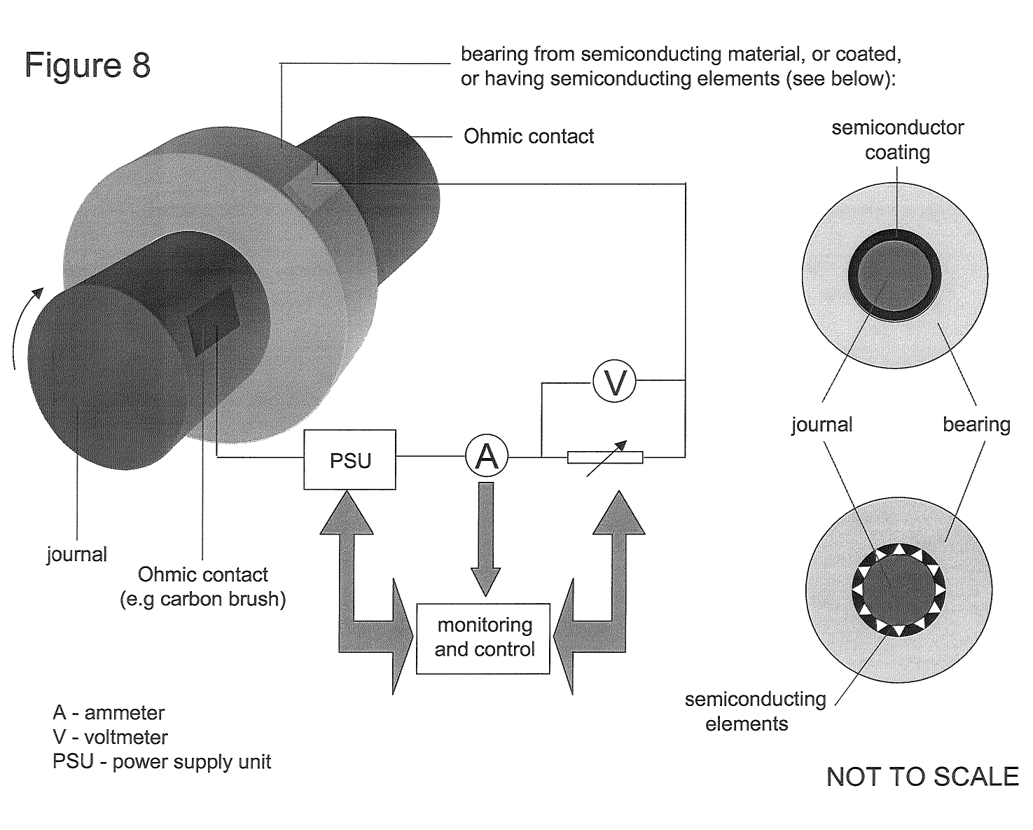

FIG. 8 is a schematic drawing of journal bearings. Ohmic contacts are formed on the journal and bearing e.g. a carbon brush for the journal. A potential is applied across the bearing and journal to induce a current across the junction between the bearings and journal. The potential and current are monitored and controlled to achieve the desired friction control. As shown in the Figure, the bearings are semiconducting, e.g. comprising a semiconducting coating or semiconducting elements and are mounted on a metal journal. Alternatively, the bearings may be from metal and the journal may be made from a semiconducting material.

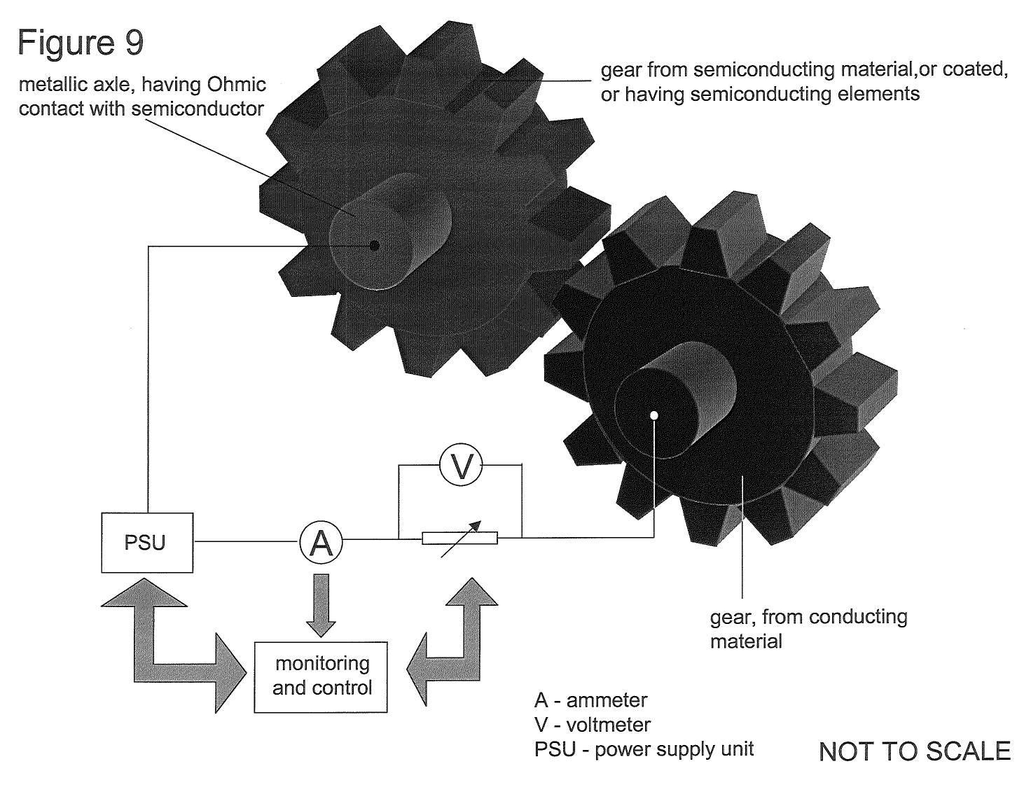

FIG. 9 is a schematic drawing of gear having a conducting gear and a semiconducting gear on a metallic axle. The metallic axle forms an ohmic contact with the semiconducting gear. A potential is applied across the axles of both gears to induce a current across the junction between the gears. The potential and current are monitored and controlled to achieve the desired friction control. The semiconducting gear may be made from a semiconducting material or comprise a semiconducting coating in contact with the metallic gear or comprise other semiconducting elements in contact with the metallic gear.

As yet, the mechanism governing the changes in friction is not completely understood, but it appears that this is a general property of many wide bandgap semiconductors and metal pairs, or other conductor-semiconductor sliding pairs.

We have thus described apparatus comprising, in use, a wide bandgap semiconductor, a conductor having an interface with the semiconductor and means for applying a potential across the interface between a conductor and semiconductor to control the friction generated between the semiconductor and the conductor.

Preferably the wide bandgap semiconductor comprises diamond or a coating of a diamond or diamond-like material. Alternatively the wide bandgap semiconductor is formed from silicon carbide (SiC), tungsten carbide (WC), boron nitride (BN), gallium nitride (GaN) or aluminium nitride (AlN). Preferably the conductor is metallic or formed from graphite, or another non-metallic conductor. Preferably the potential applied is in the range 1 kV to 5 kV. Preferably at least part of the apparatus is in a vacuum.

The apparatus may be a microelectricalmechanical system or a device for use in nanotechnology.

In some embodiments the potential is applied to reduce friction. Then the apparatus may be in the form of conventional-style bearings comprising a semiconductor made of semiconducting material and a conductor, or apparatus for machining an item, or polishing apparatus for polishing an item, or a clutch-type device.

Thus in some embodiments the apparatus comprises a conductor in the form of a tool for machining or polishing the item and, in use, a semiconductor in the form of an item to be machined or polished. In other embodiments the apparatus comprises a semiconductor is in the form of a tool for machining or polishing and, in use, a conductor in the form of an item to be machined or polished.

In some other embodiments the potential is applied to increase friction. Then the apparatus may be in the form of low-friction bearings with an integral braking mechanism or in the form of a clutch-type device.

In embodiments the apparatus comprises a sensor for sensing the temperature generated at a point of contact between the semiconductor and the conductor by the thermoelectric effect and control means for controlling friction using the sensed thermoelectric effect.

In embodiments the wide bandgap semiconductor and conductor are moveable relative to each other and the friction is generated by the relative movement of the wide bandgap semiconductor and conductor.

We have also described machining apparatus for machining a conducting item, the apparatus comprising a wide bandgap semiconducting tool which is moveable to contact a conducting item in said machining apparatus and means to apply a potential between the tool and conducting item whereby the friction generated by the relative movement between the tool and conducting item is controllable. In embodiments the tool is a drill. In embodiments the tool comprises diamond.

We have also described machining apparatus for machining a wide bandgap semiconducting item, the apparatus comprising a conducting tool which is moveable to contact a semiconducting item in said machining apparatus and means to apply a potential across the conducting tool and semiconducting item whereby the friction generated by the relative movement between the conducting tool and semiconducting item is controllable. In embodiments the tool is metallic. In embodiments the semiconducting item comprises silicon carbide (SiC), tungsten carbide (WC), boron nitride (BN), gallium nitride (GaN) or aluminium nitride (AlN).

We have also described machining apparatus for machining a semiconducting item, the apparatus comprising a metallic tool which is moveable to contact a semiconducting item in said machining apparatus and means to apply a potential across the tool and semiconducting item whereby the friction generated by the relative movement between the tool and semiconducting item is controllable. In embodiments the semiconducting item comprises silicon or germanium. In embodiments the applied potential reduces friction generated between the tool and said item.

Machining apparatus as described above may comprise a sensor for sensing the temperature generated by the thermoelectric effect at a point of contact between the tool and the item and control means for controlling friction using the sensed thermoelectric effect.

We have also described a method of controlling friction between a wide bandgap semiconductor and conductor having an interface with the semiconductor comprising applying a potential across the interface between the semiconductor and the conductor.

In some embodiments of the method the wide bandgap semiconductor comprises diamond. In other embodiments the wide bandgap semiconductor is formed from silicon carbide (SiC), tungsten carbide (WC), boron nitride (BN), gallium nitride (GaN), aluminium nitride (AlN). In embodiments the conductor is metallic. In embodiments the method comprises applying a potential in the range 1 kV to 5 kV either to reduce friction or to increase friction.

In embodiments the method may further comprise analysing the thermoelectric effect at a point of contact between the semiconductor and conductor and further modulating friction using said analysis. In embodiments the wideband semiconductor and conductor are moveable relative to each other and the friction is generated by this relative movement.

No doubt many other effective alternatives will occur to the skilled person. It will be understood that the invention is not limited to the described embodiments and encompasses modifications apparent to those skilled in the art lying within the spirit and scope of the claims appended hereto.

We claim:

1. Apparatus comprising, in use, a wide bandgap semiconductor, a conductor having an interface with the semiconductor and means for applying a potential across the interface between a conductor and the semiconductor to control the friction generated between the semiconductor and the conductor.

2. Apparatus according to claim 1, wherein the wide bandgap semiconductor comprises diamond, or a coating of a diamond or diamond-like material.

3. Apparatus according to claim 1, wherein the wide bandgap semiconductor is formed from silicon carbide (SiC), tungsten carbide (WC), boron nitride (BN), gallium nitride (GaN) or aluminium nitride (AlN)

4. Apparatus according to claim 1, wherein the potential applied is in the range 1 kV to 5 kV.

5. Apparatus according to claim 1, wherein the potential is applied to reduce friction; and wherein the apparatus is machining apparatus for machining an item, or polishing apparatus for polishing an item, or in the form of conventional-style bearings comprising a semiconductor made of semiconducting material and a conductor, or a clutch-type device,.

6. Apparatus according to claim 1, wherein the apparatus is in the form of low-friction bearings with an integral braking mechanism, or wherein the apparatus is a clutch-type device, wherein the potential is applied to reduce friction and wherein the potential is applied to increase friction.

7. Apparatus according to claim 1, comprising a sensor for sensing the temperature generated at a point of contact between the semiconductor and the conductor by the thermoelectric effect and control means for controlling friction using the sensed thermoelectric effect.

8. Apparatus according to claim 1, wherein the wide bandgap semiconductor and conductor are moveable relative to each other and the friction is generated by the relative movement of the wide bandgap semiconductor and conductor.

9. A method of controlling friction between a wide bandgap semiconductor and conductor having an interface with the semiconductor comprising applying a potential across the interface between the semiconductor and the conductor.

10. A method according to claim 9, wherein the wide bandgap semiconductor comprises diamond, or is formed from silicon carbide (SiC), tungsten carbide (WC), boron nitride (BN), gallium nitride (GaN), aluminium nitride (AlN).

11. A method according to claim 9, comprising applying a potential in the range 1 kV to 5 kV.

12. A method according to claim 9, comprising applying a potential to reduce friction.

13. A method according to claim 9, comprising analysing the thermoelectric effect at a point of contact between the semiconductor and conductor and further modulating friction using said analysis.

14. A method according to claim 9, wherein the wideband semiconductor and conductor are moveable relative to each other and the friction is generated by this relative movement.

15. Machining apparatus for machining an item, the apparatus comprising a tool which is moveable to contact a said item in said machining apparatus and means to apply a potential between the tool and item whereby the friction generated by the relative movement between the tool and conducting item is controllable; wherein one of the tool and the item is conducting, and wherein the other of the tool and the item is semiconducting.

16. Machining apparatus according to claim 15, wherein the tool comprises diamond.

17. Machining apparatus according to claim 15 wherein the other of the tool and the item is wide bandgap semiconducting.

18. Machining apparatus according to claim 15, wherein the semiconducting tool or item comprises silicon carbide (SiC), tungsten carbide (WC), boron nitride (BN), gallium nitride (GaN) or aluminium nitride (AlN), or silicon or germanium

19. Machining apparatus according to claim 15, wherein the applied potential reduces friction generated between the tool and said item.

20. Machining apparatus according to claim 15, comprising a sensor for sensing the temperature generated by the thermoelectric effect at a point of contact between the tool and the item and control means for controlling friction using the sensed thermoelectric effect.
